(19) United States
(12) Patent Application Publication
(10) Pub. No.: US 2008/0111906 A1
(43) Pub. Date: May 15, 2008

(54) Pixel circuit of CMOS image sensor for dual capture and structure thereof

(75) Inventors: Dong-Soo Kim, Seoul (KR); Gun-Hee Han, Gyeonggi-do (KR); Seog-Heon Ham, Gyeonggi-do (KR)

Correspondence Address: MILLS & ONELLO LLP, ELEVEN BEACON STREET, SUITE 605, BOSTON, MA, 02108, US

(73) Assignee: Samsung Electonics Co., Ltd., Suwon-si (KR)

(21) Appl. No.: 11/985,012

(22) Filed: Nov. 13, 2007

(30) Foreign Application Priority Data
Nov. 13, 2006 (KR) 10-2006-0111805

(51) Int. Cl. H04N 5/335; H01L 27/146

(52) U.S. Cl. 348/308; 257/292; 257/E27.133; 348/E05.091

(57) ABSTRACT

Provided is a pixel circuit in a CMOS image sensor, a structure thereof, and a method of operating the same. The pixel includes: a photodiode; a floating diffusion node connected to the photodiode through a first switch; a source follower responsive to a voltage of the floating diffusion node. The voltage of the floating diffusion node is applied to the source follower through capacitance coupling.

### CROSS-REFERENCE TO RELATED APPLICATIONS

This U.S. non-provisional patent application claims priority under 35 U.S.C. § 119 to Korean Patent Application No. 10-2006-0111805, filed on Nov. 13, 2006, the entire contents of which are hereby incorporated by reference.

### BACKGROUND OF THE INVENTION

The present invention disclosed herein relates to a Complementary Metal Oxide Semiconductor (CMOS) image sensor, and more particularly, to a pixel circuit in a CMOS image sensor.

A CMOS image sensor is installed on a mobile phone camera and a digital still camera, etc. in order to capture an image in a visual field, convert the image to an electronic signal, and transmit the electric signal into a digital signal processor. The digital signal processor performs signal processing on color image data outputted from an image capturing device, to display an image in a display device such as a Liquid Crystal Display (LCD) device.

A typical CMOS image sensor includes a pixel sensor array arranged in a matrix. Each pixel sensor includes a light device, e.g., a photodiode, which detects light and converts it into an electric signal. A dynamic range needs to be increased to improve property of the CMOS image sensor such that color rendition can be enhanced.

### SUMMARY OF THE INVENTION

In accordance with the present invention, there is provided a pixel circuit of a CMOS image censor capable of enhancing a dynamic range, a structure thereof, and a method of operating the same.

In accordance with the present invention, there is also provided a pixel circuit of a CMOS image sensor capable of dual capture, and a structure thereof, and a method of operating the same.

In accordance with one aspect of the present invention, there is provided pixels of a Complementary Metal Oxide Semiconductor (CMOS) image sensor. The pixels include: a photodiode; a floating diffusion node connected to the photodiode through a first switch; and a source follower responsive to a voltage of the floating diffusion node. The voltage of the floating diffusion node is applied to the source follower through capacitance coupling.

The first switch can be configured to connect the photodiode with the floating diffusion node twice during one frame.

The pixel structures can include: a first active region having first and second transistors and a photodiode, and including a floating diffusion node that is a connection node of the first and second transistors; and a second active region including a third transistor with a gate node. The gate node of the third transistor extends to cover a portion of the floating diffusion node of the first active region, the floating diffusion node and the gate of the third transistor are configured such that a voltage of the floating diffusion node is applied to the gate node of the third transistor through capacitance coupling.

The pixel structures can further include a dielectric layer interposed between an upper part of the floating diffusion node at the first active region and a lower part of the gate node extending from the second active region.

The gate node can extend from the second active region to cover a portion of the floating diffusion node in a fork form.

The gate node can extend from the second active region to cover a portion of the floating diffusion node and in a spiral form at the upper part of the floating diffusion node.

In accordance with still other aspect of the present invention, provided are pixels of a CMOS image sensor. The pixels include: a first transistor connected between a power source and a floating diffusion node, and configured for control by a reset signal; a second transistor including two ends and configured for control by a transfer signal, one of the two ends being connected to the floating diffusion node; a third transistor including two ends and a gate, one of the two ends being connected to the power source; and a fourth transistor connected between the other end of the third transistor and an output node, and configured for control by a select signal. A voltage of the floating diffusion node is applied to the gate of the third transistor through capacitance coupling.

The third transistor can be a source follower transistor.

The transfer signal can be activated twice during one frame.

The second transistor can connect the photodiode with the floating diffusion node twice during one frame, once in response to each of the two transfer signals.

The pixel is configured to operate in first and second capture modes during one frame, and the transfer signal is activated in each of the first and second capture modes.

The select signal can be configured to be activated in the second capture mode.

The select signal can be configured to be activated before the transfer signal during the second capture mode.

The select signal can be configured to be activated before the transfer signal during the second capture mode, and to maintain an active state until the end of the second capture mode.

In accordance with another embodiment of the present invention, provided is a CMOS image sensor that includes: a plurality of pixels arranged in a plurality of rows and columns, each of the pixels including: a first transistor connected between a power source and a floating diffusion node, and configured for control by a reset signal; a second transistor including two ends and configured for control by a transfer signal, one of the two ends being connected to the floating diffusion node; a third transistor including two ends and a gate, one of the two ends being connected to the power source; and a fourth transistor connected between the other end of the third transistor and an output node, and configured for control by a select signal such that a voltage of the floating diffusion node is applied to the gate of the third transistor through capacitance coupling.

The pixels can be configured to operate in first and second capture modes during one frame, respectively, and the transfer signals are activated in the first and second capture modes, respectively.

The select signal can be configured to sequentially select the plurality of rows and is activated in the second capture mode.

The select signal is configured to be activated before the transfer signal during the second capture mode.

Among the pixels, pixels corresponding to a second row operate in the second capture mode when pixels corresponding to a first row operate in the first capture mode.

Predetermined rows can be disposed between the first row and the second row.

In accordance with yet another aspect of the present invention, a method of operating pixels of a CMOS image sensor includes: sensing a first voltage corresponding to light; and sensing a second voltage corresponding to the light. The sensing of the first voltage includes: outputting the first voltage; sensing the second voltage; and outputting the second voltage.

The sensing of the first and second voltages can be performed during one frame.

In the method, one or more of the pixels can comprise: a first transistor connected between a power source and a floating diffusion node, and configured for control by a reset signal; a second transistor including two ends and configured for control by a transfer signal, one of the two ends being connected to the floating diffusion node; a third transistor including two ends and a gate, one of the two ends being connected to the power source; and a fourth transistor connected between another end of the two ends of the third transistor and an output node, and configured for control by a select signal, wherein the floating diffusion node and the gate of the third transistor are configured such that a voltage of the floating diffusion node is applied to the gate of the third transistor through capacitance coupling.

### BRIEF DESCRIPTION OF THE FIGURES

The accompanying figures are included to provide a further understanding of aspects of the present invention, and are incorporated in and constitute a part of this specification. The drawings illustrate exemplary embodiments in accordance with aspects of the present invention and, together with the description, serve to explain principles thereof. In the figures:

FIG. 1 is a block diagram of an embodiment of a CMOS image sensor with a pixel circuit according to aspects of the present invention;

FIG. 2 is a view of an embodiment a pixel circuit that can be used in the APS array of FIG. 1;

FIGS. 3a through 3c are plan views of embodiments of the pixel circuit of FIG. 2, in accordance with aspects of the present invention;

FIG. 4 is a view of a plurality of rows arranged in the APS array of FIG. 1; and

FIG. 5 is a view of changes of signals used in the pixel circuit of FIG. 2 when the pixel circuit performs a dual capturing process.

### DETAILED DESCRIPTION OF PREFERRED EMBODIMENTS

Hereinafter, aspects of the present invention will be described with the accompanying drawings.

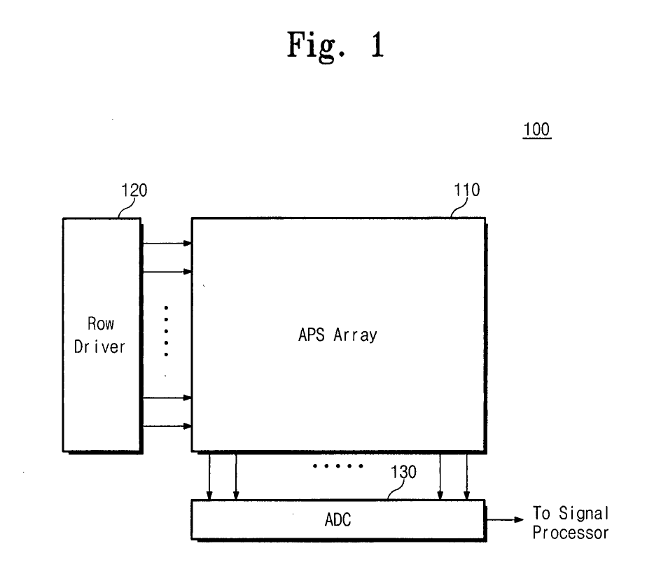

FIG. 1 is a block diagram of an embodiment of a CMOS image sensor 100 with a pixel circuit according to an aspect of the present invention. Referring to FIG. 1, the CMOS image sensor 100 includes an active pixel sensor (APS) array 110, a row driver 120, and an analog to digital converter (ADC) 130. The APS array 110 includes pixel circuits arranged in a plurality of rows and columns. A specific structure of the pixel circuit will be described later. The CMOS image sensor 100 can further include a controller that generates addressing signals for selecting the pixel circuits and outputting detected image signals. A row driver 120 sequentially selects rows of the APS array 110. The APS array 110 detects light by using a light device, e.g., a photodiode, and then converts the light to an electrical signal in order to generate image signals. Image signals outputted from the APS array 110 are analog signals corresponding to three colors R, G, and B. The ADC 130 converts the analog image signal outputted from the APS array 110 into a digital signal. The ADC 130 converts the analog image signal into the digital signal by using a correlated double sampling (CDS) method, and then delivers the digital signal into a signal processing unit. This method is very well known to those skilled in the art such that its description will be omitted for conciseness.

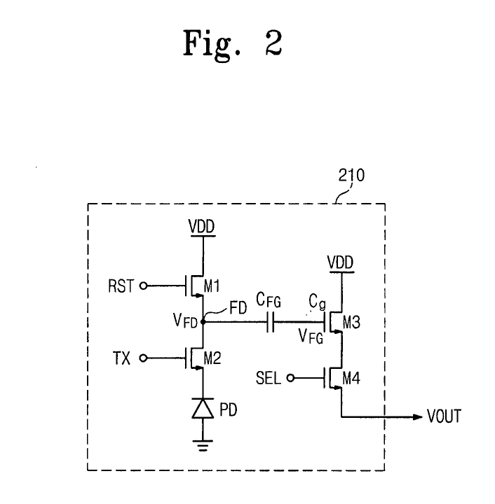

FIG. 2 is a view of an embodiment of pixel circuit 210 arranged in an APS array 100 of FIG. 1. As illustrated in FIG. 2, the one pixel circuit 210 includes four metal oxide semiconductor field effect transistors (MOSFETs) M1 to M4, and one photodiode PD.

The transistors M1 and M2 and the photodiode PD are sequentially connected in series between a supply voltage VDD and a ground voltage. The transistor M1 is controlled by a reset signal RST, and the transistor M2 is controlled by a transfer signal. The transistors M3 and M4 are sequentially connected in series between a supply voltage VDD and an output terminal. A gate of the transistor M4 is controlled by a select signal SEL and the transistor M3 operates in response to a voltage VFD of a floating diffusion node FD that is a connection node of the transistors M1 and M2. According to an aspect of the present invention, the voltage VFD of the floating diffusion node FD transfers into a gate of the transistor M3, i.e., a source follower transistor, through capacitance coupling. A capacitor CFG of FIG. 2 can be an capacitor, or a capacitor including the floating diffusion node FD and the gate of the transistor M3. The capacitor CFG will be described below.

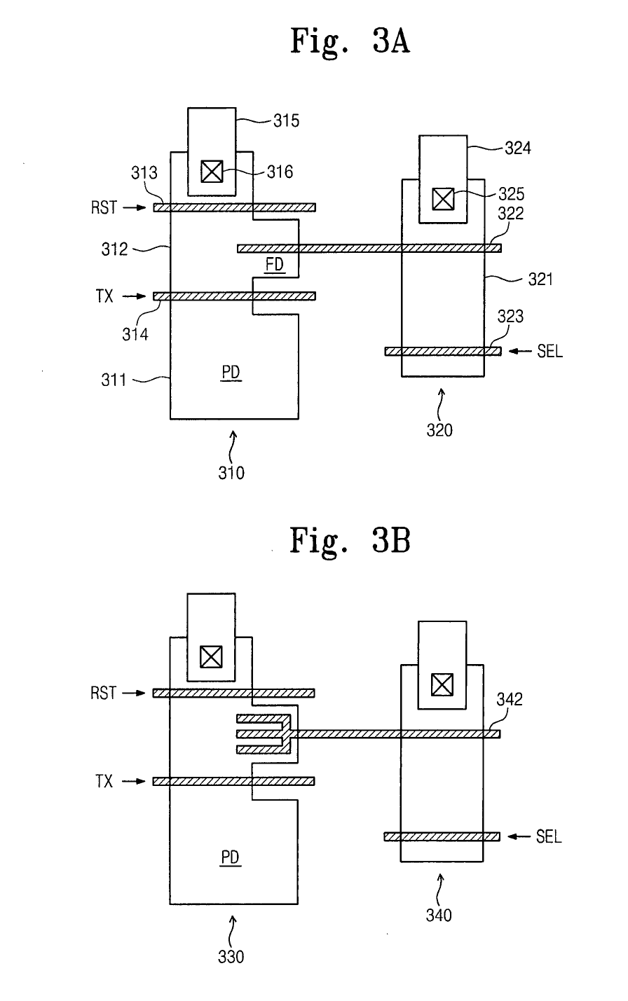

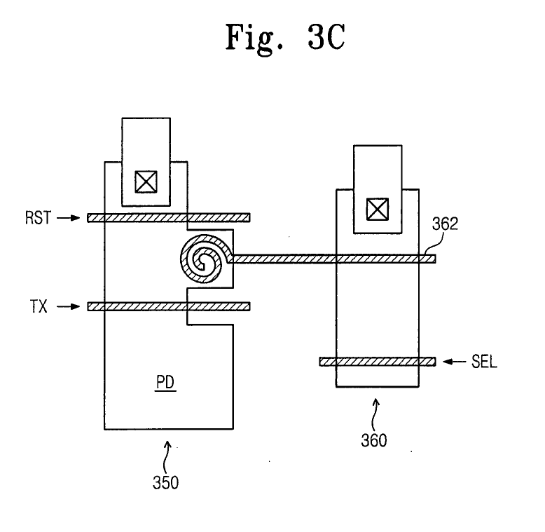

FIGS. 3a through 3c are plan views of embodiments of the pixel circuit 210 of FIG. 2, in accordance with aspects of the present invention.

Referring to FIG. 3a, the transistors M1 and M2 and the photodiode PD are formed on a first active region 310. The transistors M3 and M4 are formed on a second active region 320. The supply voltage VDD is applied to a transistor region 312 of the first active region 310 through a contact 316, and also is applied to the transistor region 312 of the second active region 320 through a contact 325.

The active region 310 and the second active region 320 are adjacently arranged with a predetermined distance, and gate electrodes of the transistors M3 and M4 are separately formed on an upper part of the transistors region 321 inside the second active region 320. The gate electrode of the transistor M3 extends from the active region 320 toward the first active region 310 to cover a portion of the floating node FD of the first active region 310. A dielectric layer is formed between the upper part of the first active region 130 and the gate electrode 322 of the transistor M3. Therefore, a voltage in the floating node FD of the first active region 310 is applied to the gate electrode through capacitance coupling, which extends from the second active region 320.

To increase the capacitance between the floating node FD of the first active region 310 and the gate electrode 322 extending from the second active region 320, as illustrated in FIG. 3b, the gate electrode 342 extends from the second active region 320 to cover a portion of the floating diffusion region of the first active region 330 in a fork form. In another example, as illustrated in FIG. 3c, the gate electrode 362 extends from the second active region 340 to cover a portion of the floating diffusion region of the first active region 350 in a spiral form. The shape of the gate electrode that is formed on the floating region of the first active region can vary in order to improve the capacitance.

Since the capacitance coupling is used to connect the floating diffusion node of the first active region and the gate of the second active region, the area of the photodiode PD can increase such that a contact can be formed. Moreover, the area increase of the photodiode PD increases a dynamic range of the pixel circuit 210.

Operations of the pixel circuit 210 will be described in more detail with reference to FIG. 2. The operations of the pixel circuit 210 with the four transistors M1 to M4 and the photodiode PD are divided into two operations. One is a reset operation for reading an initial voltage of the floating diffusion node FD and the other is a transfer operation for outputting a voltage detected in the photodiode PD.

During the reset operation, when a reset signal RST is activated into a high level in a state where a select signal SEL is activated into a high level, a voltage of the floating node FD is applied to an output signal V_{OUT} through a source follower transistor M3 and the transistor M4. At this point, the output signal V_{OUT} is a reset voltage signal VRST.

During the transfer operation, with the select signal SEL activated to a high level, when the transfer signal RST is also activated to a high level, a voltage (which is dropped by the photodiode PD) of the floating node FD is applied to the output signal V_{OUT} through the transistors M3 and M4. At this point, the output signal V_{OUT} is a sense voltage signal VSIG. The ADC 130 of FIG. 1 converts a difference between the reset voltage signal VRST and the sense voltage signal VSIG into a digital signal and delivers it into the signal processor.

Referring to FIG. 2, when the floating node FD and the gate of the source follower transistor M3 are directly connected through the contact, the voltage of the floating node FD can vary due to a current leaking through the contact. The present invention connects the floating node FD with the gate of the source follower transistor M3 through capacitance coupling, the voltage VFD of the floating node FD is applied to the gate of the source follower transistor M3. That is, since the contact connecting the floating node FD with the gate of the source follower transistor M3 is removed, the distortion of the output signals V_{OUT} decreases.

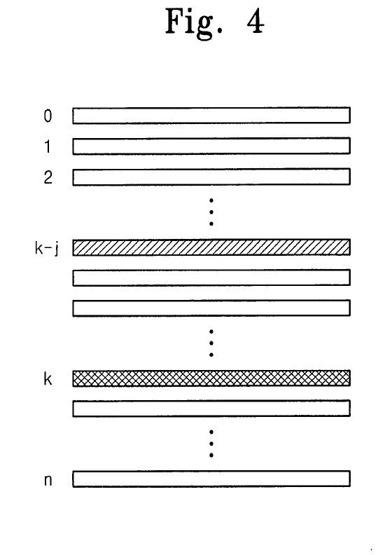

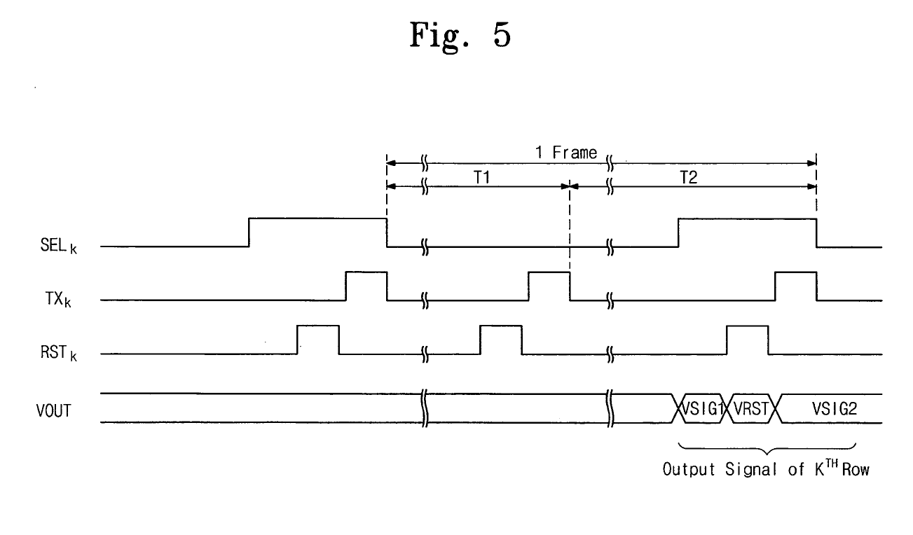

In accordance with aspects of the present invention, the floating node FD is connected with the gate of the source follower transistor M3 through capacitance coupling, such that a dual capturing operation of the pixel circuit can be possible. The dual capturing operation of the pixel circuit 210 in FIG. 2 will be described in detail with reference to FIGS. 4 and 5.

FIG. 4 is a view of a plurality of rows arranged in an APS array 110 of FIG. 1. One row includes a plurality of pixels. While pixels related to k^{th} rows are operating in a second capture mode, pixels related to k−1^{th} rows are operating in a first capture mode. Likewise, the pixels related to the two rows are simultaneously operating in the first and second capture mode, respectively.

FIG. 5 is a view of changes of signals used in a pixel circuit when the pixel circuit of FIG. 2 performs a dual capturing process. Referring to FIG. 5, a select signal SELk, a transfer signal TXk, and a reset signal RSTk are provided into the pixels related to the k^{th} rows.

One pixel circuit performs a dual capturing operation that detects light twice during one frame. That is, the pixel circuit operates in the first and second capture modes T1 and T2 during one frame. When the reset signal RSTk is activated in the first capture mode T1, a reset voltage VRST, which is a voltage of the floating node FD, is stored in the capacitor CFG. At this point, the gate voltage VFG of the source follower transistor M3 is represented in Equation 1.

$$VFG = \frac{CFG}{CFG + Cg} * VFD \qquad Equation 1$$

Continuously, when the transfer signal TXk is activated, a voltage drop occurs through the photodiode PD such that the difference between the reset voltage VRST and the sense voltage VSIG is stored in the capacitor CFG.

In the second capture mode T2, when the select signal SEL is activated, the voltage stored in the capacitor CFG is outputted as the output signal V_{OUT}. At this point, the output signal V_{OUT} is a first sense voltage signal VSIG1 corresponding to the difference between the reset voltage signal VRST and the sense voltage signal VSIG in the first capture mode T1. With the select signal SEL in an active state, when the reset signal RST is activated, a voltage of the floating diffusion node FD is applied to the capacitor CFG, and the voltage applied to the capacitor CFG is outputted as the output signal V_{OUT} through the transistors M3 and M4. At this point, the output signal V_{OUT} is a reset voltage signal VRST in the first capture mode T1. With the select signal SEL in an active state, when the transfer signal TX is activated, a voltage dropped by the photodiode PD is applied to the capacitor CFG, and is outputted as the output signal V_{OUT} through transistors M3 and M4. The output signal V_{OUT} is a second sense voltage signal VSIG2 in the second capture mode T2.

According to the embodiments, a ratio of a duration time in the first and second capture modes T1 and T2 can be controlled such that time for integrating light can be adjusted through the photodiode PD in pixel circuit 210 during the respective first and second capture modes T1 and T2. Consequently, light sensitivities in the first and second capture modes T1 and T2 are different from each other, such that a dynamic range of the pixel circuit 210 can be changed. Therefore, without changing the size of the photodiode PD in the pixel circuit 210, a dynamic range can be increased.

Additionally, signal processing is performed for improving an image quality through the first and second sense voltage signals VSIG1 and VSIG2 acquired by the dual capturing operation. The signal processing using the first and second sense voltage signals VSIG1 and VSIG2 can be performed through the signal processing unit.

According to the present invention, the floating diffusion node connected to the photodiode and the gate of the source follower transistors are connected through capacitance coupling, such that a current leakage due to a contact can be prevented. Moreover, since the floating diffusion node connected to the photodiode and the gate of the source follower transistors are connected without using the contact, the area of the photodiode can be expanded. Furthermore, the floating diffusion node connected to the photodiode and the gate of the source follower transistors are connected through capacitance coupling, such that the dual capturing operation is possible and a dynamic range of the pixel circuit can be increased.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A pixel of a Complementary Metal Oxide Semiconductor (CMOS) image sensor, the pixel comprising:
a photodiode;
a floating diffusion node connected to the photodiode through a first switch; and
a source follower responsive to a voltage of the floating diffusion node,
wherein the voltage of the floating diffusion node is applied to the source follower through capacitance coupling.

2. The pixel of claim 1, wherein the first switch is configured to connect the photodiode with the floating diffusion node twice during one frame.

3. A pixel structure of a CMOS image sensor, the pixel structure comprising:
a first active region having first and second transistors and a photodiode, and including a floating diffusion node that is a connection node of the first and second transistors; and
a second active region including a third transistor with a gate node,
wherein the gate node of the third transistor extends to cover a portion of the floating diffusion node of the first active region, the floating diffusion node and the gate of the third transistor are configured such that a voltage of the floating diffusion node is applied to the gate node of the third transistor through capacitance coupling.

4. The pixel structure of claim 3, further comprising a dielectric layer interposed between an upper part of the floating diffusion node at the first active region and a lower part of the gate node extending from the second active region.

5. The pixel structure of claim 3, wherein the gate node extends from the second active region to cover a portion of the floating diffusion node in a fork form.

6. The pixel structure of claim 3, wherein the gate node extends from the second active region to cover a portion of the floating diffusion node in a spiral form at the upper part of the floating diffusion node.

7. A pixel of a CMOS image sensor, the pixel comprising:
a first transistor connected between a power source and a floating diffusion node, and configured for control by a reset signal;
a second transistor including two ends and configured for control by a transfer signal, one of the two ends being connected to the floating diffusion node;
a third transistor including two ends and a gate, one of the two ends being connected to the power source; and
a fourth transistor connected between another end of the two ends of the third transistor and an output node, and configured for control by a select signal,
wherein the floating diffusion node and the gate of the third transistor are configured such that a voltage of the floating diffusion node is applied to the gate of the third transistor through capacitance coupling.

8. The pixel structure of claim 7, wherein the third transistor is a source follower transistor.

9. The pixel structure of claim 8, wherein the transfer signal is activated twice during one frame.

10. The pixel structure of claim 9, wherein the second transistor connects the photodiode with the floating diffusion node twice during one frame, once in response to each of the two transfer signals.

11. The pixel structure of claim 8, wherein the pixel is configured to operate in first and second capture modes during one frame, and the transfer signal is activated in each of the first and second capture modes.

12. The pixel structure of claim 11, wherein the select signal is configured to be activated in the second capture mode.

13. The pixel structure of claim 12, wherein the select signal is configured to be activated before the transfer signal during the second capture mode.

14. The pixel structure of claim 12, wherein the select signal is configured to be activated before the transfer signal during the second capture mode, and to maintain an active state until the end of the second capture mode.

15. A CMOS image sensor comprising:
a plurality of pixels arranged in a plurality of rows and columns, each of the pixels including:
a first transistor connected between a power source and a floating diffusion node, and configured for control by a reset signal;
a second transistor including two ends and configured for control by a transfer signal, one of the two ends being connected to the floating diffusion node;
a third transistor including two ends and a gate, one of the two ends being connected to the power source; and
a fourth transistor connected between the other end of the third transistor and an output node, and configured for control by a select signal,
wherein the floating diffusion node and the gate of the third transistor are configured such that a voltage of the floating diffusion node is applied to the gate of the third transistor through capacitance coupling.

16. The CMOS image sensor of claim 15, wherein the pixels are configured to operate in first and second capture modes during one frame, respectively, and the transfer signals are activated in the first and second capture modes, respectively.

17. The CMOS image sensor of claim 16, wherein the select signal is configured to sequentially select the plurality of rows and is activated in the second capture mode.

18. The CMOS image sensor of claim 17, wherein the select signal is configured to be activated before the transfer signal during the second capture mode.

19. The CMOS image sensor of claim 18, wherein, among the pixels, pixels corresponding to a second row operate in the second capture mode when pixels corresponding to a first row operate in the first capture mode.

20. The CMOS image sensor of claim 19, wherein predetermined rows are disposed between the first row and the second row.

21. A method of operating pixels of a CMOS image sensor, the method comprising:
sensing a first voltage corresponding to light; and
sensing a second voltage corresponding to the light,
wherein the sensing of the first voltage includes:
outputting the first voltage;
sensing the second voltage; and
outputting the second voltage.

22. The method of claim 21, wherein the sensing of the first and second voltages is performed during one frame.

23. The method of claim 21 wherein one or more of the pixels comprises:
a first transistor connected between a power source and a floating diffusion node, and configured for control by a reset signal;
a second transistor including two ends and configured for control by a transfer signal, one of the two ends being connected to the floating diffusion node;
a third transistor including two ends and a gate, one of the two ends being connected to the power source; and
a fourth transistor connected between another end of the two ends of the third transistor and an output node, and configured for control by a select signal,
wherein the floating diffusion node and the gate of the third transistor are configured such that a voltage of the floating diffusion node is applied to the gate of the third transistor through capacitance coupling.
